(19) United States
(12) Patent Application Publication
(10) Pub. No.: US 2023/0175168 A1
(43) Pub. Date: Jun. 8, 2023

(54) MANUFACTURING APPARATUS AND METHOD OF HIGH QUALITY ß-Ga2O3 THIN FILM GROWN BY HALIDE VAPOR PHASE EPITAXY GROWTH

(71) Applicant: Korea Institute of Ceramic Engineering and Technology, Gyeongsangnam-do (KR)

(72) Inventors: Dae-Woo JEON, Gyeongsangnam-do (KR); Ji-Hyeon Park, Jeollabuk-do (KR)

(73) Assignee: Korea Institute of Ceramic Engineering and Technology, Gyeongsangnam-do (KR)

(21) Appl. No.: 18/053,989

(22) Filed: Nov. 9, 2022

(30) Foreign Application Priority Data
Dec. 6, 2021 (KR) 10-2021-0172667
Dec. 28, 2021 (KR) 10-2021-0189525

(51) Int. Cl. C30B 29/16; C30B 25/14; C30B 25/16; C30B 33/02

(52) U.S. Cl. CPC C30B 29/16; C30B 25/14; C30B 25/165; C30B 33/02

(57) ABSTRACT

Proposed is a manufacturing method of a high-quality β-Ga₂O₃ thin film using a high-quality β-Ga₂O₃ thin film manufacturing apparatus based on halide vapor phase epitaxy (HVPE) growth. The apparatus includes a reaction gas generating unit in which a chlorine-based gas and Ga in a source zone react to generate GaClx, a dopant gas supply unit, an additional chlorine-based gas supply unit for supplying an additional chlorine-based gas in a source tube, oxygen-based gas supply units, and a susceptor unit supporting a substrate on which a Ga₂O₃ thin film is to be formed. During the epitaxial growth, the additional hydrogen chloride (HCl) gas is supplied to reduce the pre-reaction between precursors, and a movement distance to the susceptor can is increased to increase growth rate and growth speed to control the crystallinity. Thus, high-quality epitaxial growth and a high production yield can be achieved.

### CROSS REFERENCE TO RELATED APPLICATION

The present application claims priority to Korean Patent Application No. 10-2021-0172667, filed Dec. 6, 2021 and Korean Patent Application No. 10-2021-0189525, filed Dec. 28, 2021 the entire contents of which is incorporated herein for all purposes by this reference.

### BACKGROUND OF THE DISCLOSURE

### 1. Field of the Disclosure

The present disclosure relates to a method of manufacturing a high-quality β-Ga₂O₃ thin film. More particularly, the present disclosure relates to a method and apparatus for manufacturing a high-quality β-Ga₂O₃ thin film through epitaxial growth, the method and apparatus using a halide vapor phase epitaxy (HVPE) process that enables high-quality epitaxial growth and can improve a production yield by additionally feeding a hydrogen chloride (HCl) gas during the epitaxial growth of a thin film to reduce pre-reaction between precursors and by increasing a movement distance to a susceptor to increase the growth rate and control crystallinity.

A national project supported by government associated with this invention is described below.
Project Unique Number 1711119126
Project Serial Number 2020M3H4A3081796
Government Department Ministry of Science and ICT
Specialized Institution National Research Foundation of Korea for Project Management
Title of Research Material Innovation Leading Project Business
Title of Project Commercialization technology for 4-inch large-diameter gallium oxide epitaxial growth for 2.5 kV vertical and horizontal power semiconductor devices
Contribution Rate 1/1
Supervising Institute Korea Institute of Ceramic Engineering and Technology
Research Period 2020.05.15-2024.12.31

### 2. Description of the Related Art

Existing Si-based power semiconductor devices have reached limits in performance improvement, compared to technology development, due to inherent physical property limitations. As a result, industrial demands for power semiconductor materials with wide-bandgap (WBG) properties and ultra-wide bandgap (UWB) properties have gradually grown.

UWB β-Ga₂O₃ materials are used as wafers for next-generation power semiconductors with cost-competitiveness, as the manufacturing costs thereof are approximately 1/3 to 1/5 cheaper than that of GaN materials or SiC materials. β-Ga₂O₃ epitaxial growth is a technology for growing a single-crystal layer of β-Ga₂O₃ on a homogeneous substrate of β-Ga₂O₃, or for growing a single-crystal layer of α-Ga₂O₃ on a heterogeneous substrate such as sapphire. That is, Ga₂O₃ epitaxial growth includes technologies for obtaining high-quality single-crystal layers and doping techniques for obtaining n-type doping characteristics.

Ga₂O₃ materials are present mostly in the form of β-Ga₂O₃, which is the most stable form, and also can be present in 4 different phases (α, β, δ, ε).

β-Ga₂O₃ is the most stable form at high-temperature ranges and thus can be easily used to grow ingots. α-Ga₂O₃ is a relatively stable form at low-temperature ranges of 500° C. or less. The remaining types are meta-stable forms and thus exist unstably.

FIG. 1 is a diagram illustrating the construction of an apparatus for manufacturing a β-Ga₂O₃ thin film in the conventional method, FIG. 2 is a diagram showing problems occurring in the conventional method, and FIG. 3 is a diagram showing β-Ga₂O₃ thin film surfaces in the conventional method.

In the conventional method, during an epitaxial growth process, pre-reactions between GaClx and oxygen generate powders. As shown in FIG. 2, such powders form crystals at a terminal end of a source tube, so there has been a problem of clogging.

In addition, since such powders are observed on a surface of thin films, there has been a problem in that high-quality epitaxial growth is difficult to achieve.

### SUMMARY OF THE INVENTION

The present disclosure has been made to provide solutions to the above problems. An objective of the present disclosure is to provide an apparatus and method for manufacturing a high-quality β-Ga₂O₃ thin film through halide vapor phase epitaxy (HVPE) growth. During the epitaxial growth process of forming the thin film, an additional hydrogen chloride (HCl) gas is supplied to reduce pre-reaction between precursors, and a moving distance to a susceptor is increased to increase the growth rate and control crystallinity, resulting in high-quality epitaxial growth and an increase in production yield.

Another objective of the present disclosure is to provide a method and apparatus for manufacturing a high-quality β-Ga₂O₃ thin film, using a HVPE growth process capable of reducing a pre-reaction between GaClx and O₂ and a pre-reaction between SiH₄ and O₂ to increase growth rate and doping concentration, respectively.

To accomplish the above objectives, the present disclosure provides an apparatus for manufacturing a high-quality β-Ga₂O₃ thin film through halide vapor phase epitaxy (HVPE) growth. The apparatus includes: a reaction gas generating unit configured to produce GaClx through a reaction between a chlorine-based gas and Ga in a source zone; a dopant gas supply unit configured to supply a dopant gas; an additional chlorine-based gas supply unit configured to supply an additional chlorine-based gas in a source tube; oxygen-based gas supply units configured to supply an oxygen-based gas; and a susceptor unit configured to support a substrate on which a β-Ga₂O₃ thin film is to be formed. The additional chlorine-based gas reduces a pre-reaction between the GaClx and oxygen, to facilitate formation of Ga₂O₃ on a surface of the substrate.

In the present disclosure, a first guide member may be provided to enhance reactivity between the chlorine-based gas and Ga in the source zone by shortening a passage route for the chlorine-based gas in an internal space of the source zone.

The first guide member may be curved toward an inlet or outlet of the reaction gas generating unit.

On the other hand, a second guide member may be provided on an outlet side of the dopant gas supply unit to minimize an influence on a flow of the GaClx generated in the reaction gas generating unit and to prevent direct contact between the dopant gas and the GaClx.

The second guide member is characterized to be inclined toward a nozzle of the source tube.

In the present disclosure, the susceptor unit is vertically installed to be spaced from the nozzle of the source tube by a predetermined distance. Preferably, the predetermined distance between the nozzle of the source tube and the susceptor unit is in a range of 5 cm to 11 cm.

In addition, the chlorine-based gas and the additional chlorine-based gas may be HCl gas.

Furthermore, the nozzle of the source tube may have a shower head structure with a plurality of through holes.

On the other hand, in order to accomplish the above objectives, the present disclosure provides a method of manufacturing a high-quality β-Ga₂O₃ thin film through halide vapor phase epitaxy (HVPE) growth. The manufacturing method includes: generating GaClx as a reaction gas through a reaction between a chlorine-based gas and Ga in a source zone; supplying a dopant gas through a dopant gas supply unit; supplying an oxygen-based gas through oxygen-based gas supply units; supplying an additional chlorine-based gas in a source tube; and epitaxially growing a doped Ga₂O₃ epitaxial layer through a reaction between the GaClx, the oxygen-based gas, and the dopant gas on a substrate.

In this case, in the supplying of the additional chlorine-based gas, HCl gas may be supplied at a flow rate in a range of 50 sccm to 80 sccm.

In addition, the manufacturing method may further include in-situ annealing after the epitaxial growth.

According to the present disclosure as described above, during an epitaxial growth process of a thin film through halide vapor phase epitaxy (HVPE) growth. During the epitaxial growth process of forming the thin film, an additional hydrogen chloride (HCl) gas flow can be supplied to reduce pre-reaction between precursors, and a movement distance to a susceptor can be increased to increase the growth rate and control crystallinity, resulting in high-quality epitaxial growth and an increase in production yield.

In addition, pre-reaction between GaClx and O₂ can be reduced to increase the growth rate, and pre-reaction between SiH₄ and O₂ can be reduced to increase a doping concentration.

### BRIEF DESCRIPTION OF THE DRAWINGS

FIG. 1 is a diagram illustrating the construction of an apparatus for manufacturing a β-Ga₂O₃ thin film in the related art;

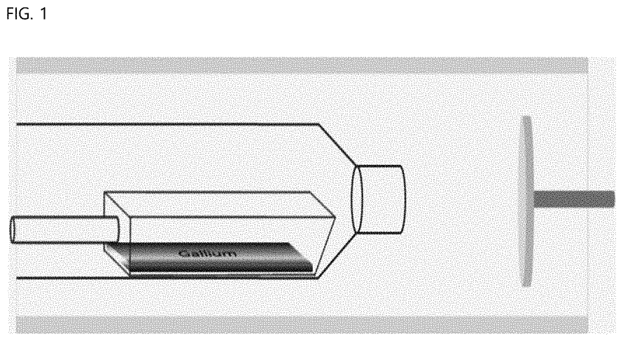

FIG. 2 is a diagram showing problems occurring in the related art;

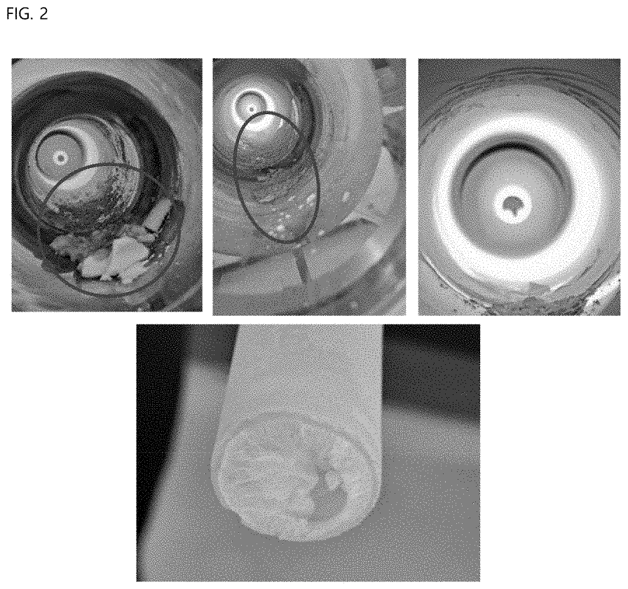

FIG. 3 is a diagram showing β-Ga₂O₃ thin film surfaces in the related art;

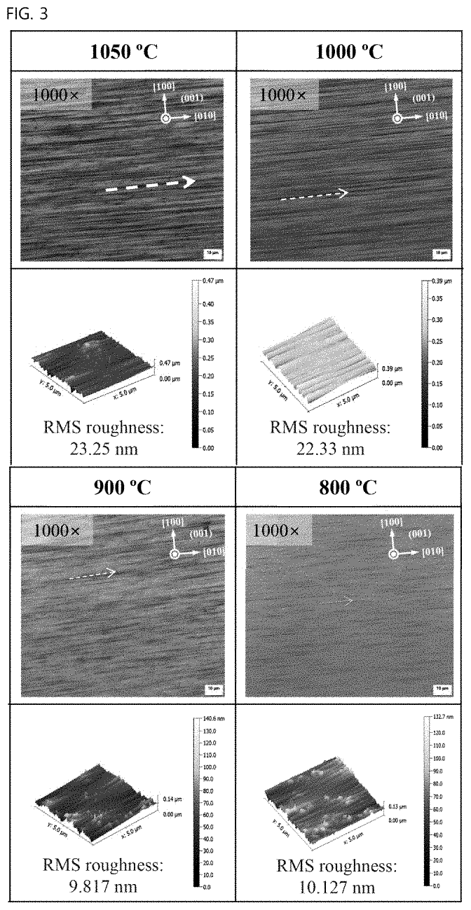

FIG. 4 is a diagram of graphs showing intensity and full width at half maximum (FWHM) values of a β-Ga₂O₃ thin film in the related art;

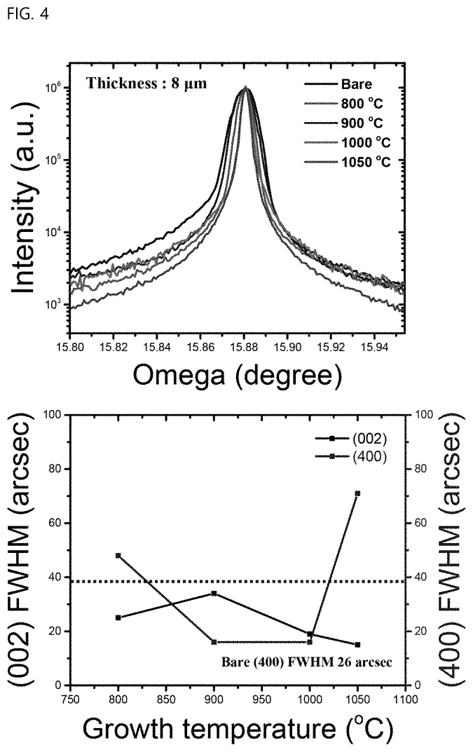

FIGS. 5 and 6 are diagrams illustrating the construction of an apparatus for manufacturing a high-quality β-Ga₂O₃ thin film and gas flow therein according to the present disclosure;

FIG. 7 is a flow chart illustrating a method of manufacturing a high-quality β-Ga₂O₃ thin film according to the present disclosure;

FIG. 8 is a diagram showing β-Ga₂O₃ thin film surfaces, the β-Ga₂O₃ thin films manufactured by a method of manufacturing a high-quality β-Ga₂O₃ thin film according to the present disclosure;

FIG. 9 is a diagram of graphs showing measurement results of thin film thickness according to HCl gas flow rate in the present disclosure; and

FIGS. 10 to 12 are diagrams of graphs showing β-Ga₂O₃ thin film properties manufactured by a method of manufacturing a high-quality β-Ga₂O₃ thin film, the properties such as thin film growth rate according to HCl gas flow rate in the present disclosure.

### DESCRIPTION OF THE PREFERRED EMBODIMENTS

Hereinafter, a method of manufacturing a high-quality β-Ga₂O₃ thin film through halide vapor phase epitaxy (HVPE) growth, according to a preferred embodiment of the present disclosure, will be described in detail with reference to the accompanying drawings.

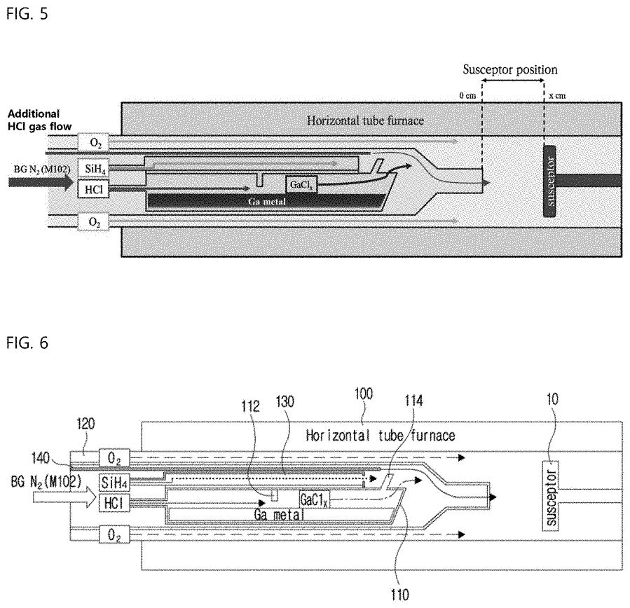

FIGS. 5 and 6 are diagrams illustrating the construction of an apparatus for manufacturing the high-quality β-Ga₂O₃ thin film and gas flow therein according to the present disclosure,

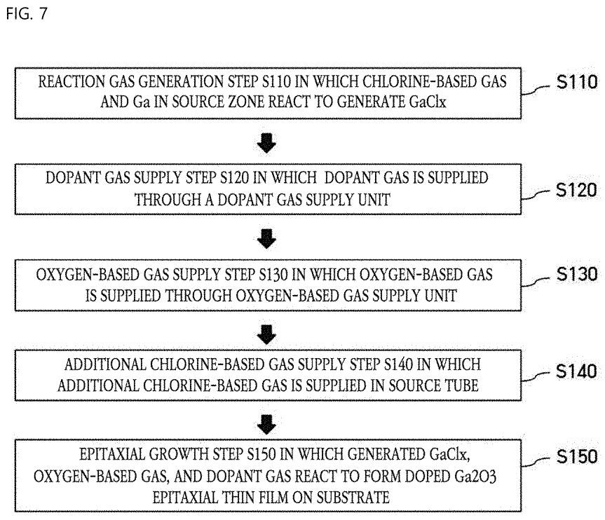

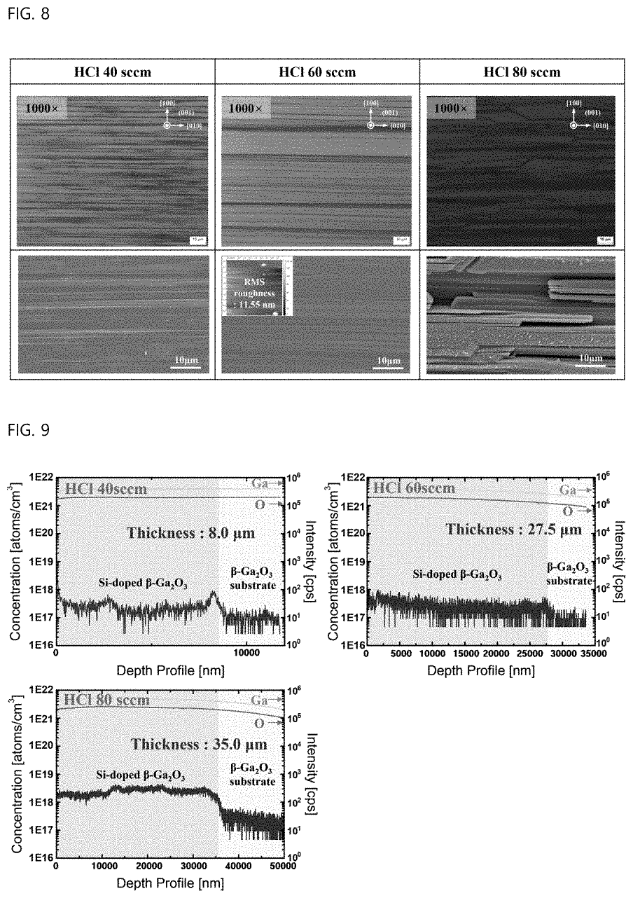

FIG. 7 is a flow chart illustrating the method of manufacturing the high-quality β-Ga₂O₃ thin film according to the present disclosure, and FIG. 8 is a diagram showing β-Ga₂O₃ thin film surfaces, the β-Ga₂O₃ thin films manufactured by the method of manufacturing the high-quality β-Ga₂O₃ thin film according to the present disclosure.

Referring to FIGS. 5 and 6, a high-quality β-Ga₂O₃ thin film manufacturing apparatus 100 based on HVPE growth includes: a reaction gas generating unit 110 configured to produce GaClx by causing a reaction between a chlorine-based gas and Ga in a source zone; a dopant gas supply unit 130 configured to supply a dopant gas; an additional chlorine-based gas supply unit 140 configured to supply an additional chlorine-based gas in a source tube; oxygen-based gas supply units 120 configured to supply an oxygen-based gas; and a susceptor unit 10 configured to support a substrate on which a β-Ga₂O₃ thin film is to be formed. The additional chlorine-based gas reduces a pre-reaction between the GaClx and oxygen to facilitate formation of Ga₂O₃ on a surface of the substrate.

The present disclosure features that the additional chlorine-based gas supply unit 140 that supplies the additional chlorine-based gas in the source tube during the growth of the β-Ga₂O₃ thin film is added to prevent the generation of powder by the pre-reaction between the GaClx and oxygen.

That is, as illustrated in FIGS. 5 and 6, the additional chlorine-based gas supply unit 140 for supplying the additional chlorine-based gas, apart from the chlorine-based gas (HCl) supplied for reaction with Ga in the source zone, is provided inside the source tube to reduce the pre-reaction between the GaClx and oxygen.

In this case, the additional chlorine-based gas supply unit 140 is a gas inlet passage provided at an upper portion of the source tube. Alternatively, the additional chlorine-based gas supply 140 may be a separate tube. In one embodiment of the present disclosure, a ¼-inch quartz tube is used. The additional chlorine-based gas supply unit 140 has at least one gas inlet positioned in the source tube to facilitate the supply of the additional chlorine-based gas.

When the additional hydrogen chloride (HCl) gas is introduced during the thin film epitaxial growth as described above, the pre-reaction between the GaClx and oxygen can be reduced. In addition, a movement distance to the susceptor is increased, and thus the growth rate and growth speed of the thin film increase. Furthermore, high-quality epitaxial growth is enabled by inhibiting the generation of powder.

In the present disclosure, HCl gas is used as the chlorine-based gas and the additional chlorine-based gas. In addition, SiH₄ (at a concentration of 2000 ppm) is used as the dopant gas. It is obvious that various n-type or p-type impurity dopants other than SiH₄ can be used.

In the present disclosure as described above, the reaction gas generating unit 110 includes a first guide member 112 to enhance reactivity between the chlorine-based gas and Ga in the source zone by shortening a passage route for the chlorine-based gas in an internal space of the source zone.

The first guide member 112 is a component to facilitate the reaction between the Ga and HCl gas flowing into the source zone. The first guide member 112 reduces the length of the passage route for the HCl gas so that the HCl gas can flow in close proximity to the Ga.

To this end, as illustrated in FIGS. 5 and 6, the first guide member 112 has a barrier or a projection protruding downward from an upper inner surface of the reaction gas generating unit 110.

In this case, the height of the first guide member 112 may vary according to the size of the Ga source zone or the size of the reaction gas generating unit 110.

In addition, a device for adjusting the height of the first guide member 112 may be added to cause the HCl gas flowing into the source zone to be in close contact with the Ga metal according to the amount of Ga metal consumed so that the reaction between the Ga and HCl gas can be facilitated. In this case, it is preferable to install a sensor that measures the remaining amount (or height) of the Ga metal. In addition, it is preferable to adjust the height of the first guide member 112 according to a signal detected by the sensor.

On the other hand, the first guide member 112 may be curved toward an inlet or outlet of the reaction gas generating unit 110.

That is, although the first guide member 112 is illustrated to have a rectangular cross section in FIGS. 5 and 6, the cross-sectional shape of the first guide member 112 is not limited thereto. The cross-sectional shape of the first guide member 112 may be curved toward the inlet of the reaction gas generating unit 110 into which the HCl gas is introduced or the outlet of the reaction gas generating unit 110 from which the HCl gas is discharged so that the HCl gas can easily flow.

On the other hand, the outlet side of the dopant gas supply unit 130 is provided with a second guide member 114 to minimize an influence the GaClx flow formed by the reaction gas generating unit 110 and to prevent direct contact between the dopant gas and the GaClx.

The second guide member 114 is formed on an exterior surface of the reaction gas generating unit 110 and positioned between the outlet of the dopant gas supply unit 130 and the outlet of the reaction gas generating unit 110 to prevent direct contact between the dopant gas and the GaClx.

In this case, the second guide member 114 is preferably inclined toward a nozzle of the source tube to facilitate the flow of the dopant gas toward the nozzle of the source tube. That is, when the second guide member 114 vertically extends, the second guide member 114 can serve as a barrier wall that prevents direct contact between the dopant gas and the GaClx but is likely to obstruct the flow of the dopant gas. Therefore, the second guide member 114 is preferably inclined toward the nozzle of the source tube so that the dopant gas can be easily introduced into the nozzle of the source tube along the second guide member 114.

In the present disclosure, the susceptor unit 10 is vertically installed to be spaced from the nozzle of the source tube by a predetermined distance. Preferably, the distance between the nozzle of the source tube and the susceptor unit 10 is in a range of 5 cm to 11 cm.

The nozzle of the source tube preferably has a shower head structure with a plurality of through holes so that the GaClx can be uniformly discharged through the nozzle of the source tube.

A high-quality β-Ga₂O₃ thin film manufacturing method using the HVPE-based high-quality β-Ga₂O₃ thin film manufacturing apparatus structured as described will be described below.

The manufacturing method includes: a reaction gas generation step S110 in which a chlorine-based gas and Ga in a source zone react to generate GaClx; a dopant gas supply step S120 in which a dopant gas is supplied through a dopant gas supply unit 130; an oxygen-based gas supply step S130 in which an oxygen-based gas is supplied through oxygen-based gas supply units 120; an additional chlorine-based gas supply step S140 in which an additional chlorine-based gas is supplied in a source tube; and an epitaxial growth step S150 in which the generated GaClx, the oxygen-based gas, and the dopant gas react to form a doped Ga₂O₃ epitaxial thin film on a substrate.

The present disclosure features the additional chlorine-based gas supply step S140 in which the additional chlorine-based gas is supplied to the source tube to prevent the generation of powder by the pre-reaction between the GaClx and the oxygen during the β-Ga₂O₃ thin film growth.

As described above, the additional chlorine-based gas supply unit 140 capable of supplying the additional chlorine-based gas, apart from the chlorine-based gas (HCl) supplied for reaction with Ga in the source zone, is provided in the source tube to reduce the pre-reaction between the GaClx and oxygen.

When the additional hydrogen chloride (HCl) gas is supplied during the thin film epitaxial growth process, the pre-reaction between the GaClx and oxygen can be reduced. In addition, a movement distance to the susceptor is increased, and thus the growth rate and growth speed of the thin film increase. Furthermore, high-quality epitaxial growth can be enabled by inhibiting the generation of powder.

In this case, in the additional chlorine-based gas supply step, the HCl gas is supplied at a flow rate in a range of 20 sccm to 100 sccm. Most preferably, the HCl gas is supplied at a flow rate in the range of 50 sccm to 80 sccm.

It is confirmed from FIG. 8 that the gas flow rate of the additional HCl gas affects surface texture and the pre-reaction between the GaClx and oxygen.

Specifically, the surface texture varies significantly according to the flow rate of the additional HCl gas, for example, at 40 sccm, 60 sccm, and 80 sccm. When the additional HCl gas is supplied at a flow rate of 40 sccm, the formed β-Ga₂O₃ thin film surface has no significant difference from existing β-Ga₂O₃ thin film surfaces. However, in this case, the growth rate increases, and the generated powder has a small particle size.

When the additional HCl gas is supplied at a flow rate of 60 sccm, it is confirmed that almost no powder is observed and the growth rate is high. When the additional HCl gas is supplied at a flow rate of 80 sccm, it is confirmed that cracks occur on the surface of the 13-Ga₂O₃ thin film due to the excessively high growth rate.

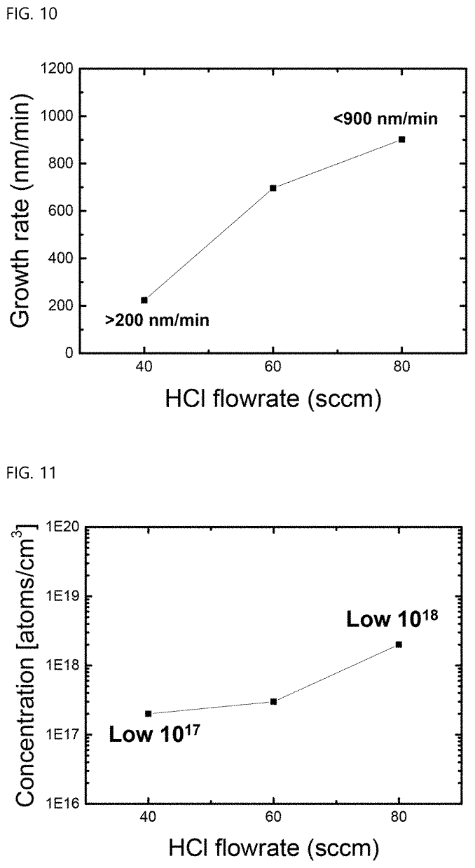

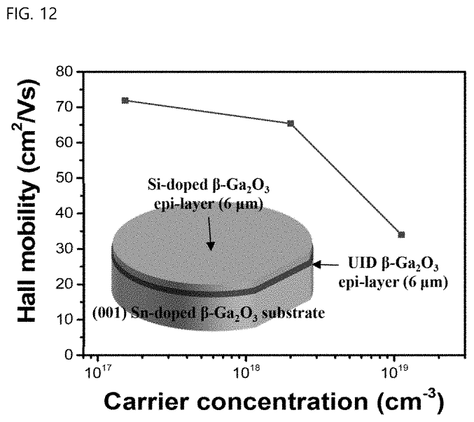

Furthermore, as shown in FIGS. 9 and 10, when the flow rate of the additional HCl gas is increased, the growth rate significantly increases from 200 nm/min to 900 nm/min.

As shown in the drawings, since the flow rate of the additional HCl gas affects the surface texture and the pre-reactions between GaClx and oxygen, it is preferable to supply the HCl gas at a flow rate in a range of 50 sccm to 80 sccm in the additional chlorine-based gas supply step.

On the other hand, in the present disclosure, the method may further include an in-situ annealing step performed after the epitaxial growth step.

In the annealing step, the in-situ annealing is performed in which annealing is performed under a N₂ or Ar gas atmosphere without a doping gas immediately after the completion of the formation of the doped layer.

In the present disclosure, the in-situ annealing is performed immediately after the completion of the growth of the doped layer to maximize the lattice rearrangement effect in the grown epitaxial layer and the dopant activation effect.

Table 1 shows evaluation results of electrical properties according to in-situ annealing time.

TABLE 1

| In-situ annealing | Carrier concentration | Mobility |
|---|---|---|
| time (min) | (/cm³) | (cm²/V · s) |
| 0 | 1.54 × 10¹⁷ | 71.9 |
| 5 | 1.88 × 10¹⁸ | 70.2 |
| 10 | 1.13 × 10¹⁹ | 34.0 |

As shown in Table 1, a heat treatment for the in-situ annealing is required to be performed under a N₂ atmosphere to activate all of the dopants.

On the other hand, the inside of the reaction gas generating unit 110 is provided with a first guide member 112 which reduces the passage route for the chlorine-based gas in the source zone and enhances reactivity between the chlorine-based gas and Ga in the source zone.

The first guide member 112 is a component to facilitate the reaction between the Ga and the HCl gas flowing into the source zone. Due to the reduction in the passage route for the HCl gas, the HCl gas flows in close contact with the Ga.

Therefore, in the reaction gas generation step, the reactivity between the chlorine-based gas and Ga in the source zone can be enhanced due to the presence of the first guide member 112 that reduces the passage route for the chlorine-based gas in the internal space of the source zone.

In addition, in the dopant gas supply step, a second guide member 114 is installed at the outlet side of the dopant gas supply unit 130 to minimize an influence on the flow of the GaClx generated in the reaction gas generating unit 110 and to prevent the direct contact between the dopant gas and the GaClx.

According to the present disclosure described above, the pre-reaction between GaClx and O₂ is reduced to increase the growth rate, and the pre-reaction between SiH₄ and O₂ is reduced to increase a doping concentration.

Although the preferred embodiments of the present invention have been disclosed for illustrative purposes, those skilled in the art will appreciate that various modifications, additions and substitutions are possible, without departing from the scope and spirit of the invention as disclosed in the accompanying claims.

What is claimed is:

1. An apparatus for manufacturing a high-quality β-Ga₂O₃ thin film through halide vapor phase epitaxy (HVPE) growth, the apparatus comprising:
a reaction gas generating unit configured to produce GaClx through a reaction between a chlorine-based gas and Ga in a source zone;
a dopant gas supply unit configured to supply a dopant gas;
an additional chlorine-based gas supply unit configured to supply an additional chlorine-based gas in a source tube;
oxygen-based gas supply units configured to supply an oxygen-based gas; and
a susceptor unit configured to support a substrate on which a β-Ga₂O₃ thin film is to be formed,
wherein the additional chlorine-based gas reduces a pre-reaction between the GaClx and oxygen, to facilitate formation of Ga₂O₃ on a surface of the substrate.

2. The apparatus of claim 1, further comprising a first guide member provided to enhance reactivity between the chlorine-based gas and Ga in the source zone by shortening a passage route for the chlorine-based gas in an internal space of the source zone.

3. The apparatus of claim 2, wherein the first guide member is curved toward an inlet or outlet of the reaction gas generating unit.

4. The apparatus of claim 1, further comprising a second guide member provided on an outlet side of the dopant gas supply unit to minimize an influence on a flow of the GaClx generated in the reaction gas generating unit and to prevent direct contact between the dopant gas and the GaClx.

5. The apparatus of claim 4, wherein the second guide member is inclined toward a nozzle of the source tube.

6. The apparatus of claim 1, wherein the susceptor unit is vertically installed to be spaced from the nozzle of the source tube by a predetermined distance.

7. The apparatus of claim 6, wherein the predetermined distance between the nozzle of the source tube and the susceptor unit is in a range of 5 cm to 11 cm.

8. The apparatus of claim 1, wherein the chlorine-based gas and the additional chlorine-based gas are HCl gas.

9. The apparatus of claim 1, wherein the nozzle of the source tube has a shower head structure with a plurality of through holes.

10. A method of manufacturing a high-quality β-Ga₂O₃ thin film through halide vapor phase epitaxy (HVPE) growth, the method comprising:
generating GaClx as a reaction gas through a reaction between a chlorine-based gas and Ga in a source zone;
supplying a dopant gas through a dopant gas supply unit;
supplying an oxygen-based gas through oxygen-based gas supply units;
supplying an additional chlorine-based gas in a source tube; and
epitaxially growing a doped Ga₂O₃ epitaxial layer through a reaction between the GaClx, oxygen-based gas, and dopant gas on a substrate.

11. The method of claim 10, wherein in the supplying of the additional chlorine-based gas, HCl gas is supplied at a flow rate in a range of 50 sccm to 80 sccm.

12. The method of claim 10, further comprising in-situ annealing performed after the epitaxial growth.

13. The method of claim 10, wherein in the generating of the reaction gas, a first guide member is provided to enhance reactivity between the chlorine-based gas and Ga in the source zone by shortening a passage route for the chlorine-based gas in an internal space of the source zone.

14. The method of claim 10, wherein in the supplying of the dopant gas, a second guide member is formed on an outlet side of the dopant gas supply unit to minimize an influence on a flow of the GaClx generated in the reaction gas generating unit and to prevent direct contact between the dopant gas and the GaClx.
